(19) United States
(12) Patent Application Publication
(10) Pub. No.: US 2020/0011652 A1
(43) Pub. Date: Jan. 9, 2020

(54) INTERFEROMETRY SYSTEM AND METHODS FOR SUBSTRATE PROCESSING

(71) Applicant: Applied Materials, Inc., Santa Clara, CA (US)

(72) Inventors: Benjamin M. JOHNSTON, Los Gatos, CA (US); Cheuk Ming LEE, Castro Valley, CA (US); Jae Myung YOO, San Jose, CA (US); Glen Alan GOMES, San Jose, CA (US); David Michael CORRIVEAU, Sacramento, CA (US); Thang Duc NGUYEN, Milpitas, CA (US)

(21) Appl. No.: 16/026,982

(22) Filed: Jul. 3, 2018

(51) Int. Cl. G01B 9/02; G03F 7/20

(52) U.S. Cl. CPC G01B 9/02087; G01B 9/02007; G01B 9/02003; G01B 2290/70; G03F 7/70775; G01B 2290/45; G01B 9/02019

(57) ABSTRACT

Processing systems and methods used in the manufacturing of flat panel displays (FPDs) are provided herein. In one embodiment, a processing system features a motion stage movably disposed on a base surface, one or more X-position interferometers, and a plurality of Y-position interferometers. The X-position interferometers include an X-position mirror fixedly coupled to the motion stage and an X-axis stationary module fixedly coupled a non-moving surface of processing system. Each of the plurality of Y-position interferometers include one of a first or second Y-position mirror fixedly coupled to the motion stage in orthogonal relationship to the one or more X-position mirrors and one of a first or a second Y-axis stationary module fixedly coupled to a non-moving surface of the processing system. Here, each of the Y-axis stationary modules is positioned to direct coherent radiation towards a respective Y-position mirror when the Y-position interferometer thereof is in an active arrangement.

### BACKGROUND

### Field

Embodiments of the present disclosure generally relate to the field of electronic device manufacturing, and more particularly, to interferometry systems and methods used for substrate processing in the manufacturing of flat panel displays and other large area substrates.

### Description of the Related Art

Direct write lithography (DWL) systems are used in the manufacturing of flat panel displays (FPDs) to form a plurality of individual display devices on a single large area substrate. Examples of individual display devices include computer monitor screens, touch panel device screens, cell phone screens, and television screens. The substrate is typically a thin rectangular sheet of glass, plastic, or a combination thereof, which, once processed, is then divided into the individual display devices or panels formed thereon.

In a typical DWL process one or more lithography exposure sources, such as a UV light source, is used to direct and, or, focus radiation to, on, or below the surface of a photo-sensitive resist layer deposited on a surface of the substrate. Often the substrate is disposed on, and secured to, a dual axis motion stage which moves the substrate under the lithography exposure source enabling a desired exposure pattern to be formed in the resist layer.

For example, in FIG. 1A hereof a substrate 101, having a photo-sensitive resist layer disposed on a surface thereof, is vacuum chucked to an X-Y linear motion stage 103. Here, the motion stage 103 moves (scans) the substrate 101 in a first Y direction 104a. Simultaneously, a lithography exposure source 105 facing the substrate 101 directs and, or, focuses one or more UV write beams 106 onto or below a surface of the photo-sensitive resist layer to form an exposure pattern therein. FIG. 1A illustrates a serpentine print path 107 where at the end of a scan length L the motion stage 103 will move (step) the substrate 101 a step width W in an X-direction 108. The motion stage 103 then scans the substrate 101 in a second Y direction 104b opposite the first Y direction 104a while an exposure pattern is simultaneously formed in the resist layer using the lithography exposure source 105. Typically, the movement of the motion stage 103 and the operation of the lithography exposure source 105 are coordinated by a system controller 109. The system controller 109 receives positional information of the motion stage from a positioning system, such as one or both of a system of linear optical encoders (not shown) and a system of interferometer encoders (not shown).

Generally, a processing system designed to handle and process larger area substrates is desirable over processing systems designed to handle relativity smaller substrates due to economies of scale. However, scaling the positioning systems conventionally used with DWL processing systems to support the next generation of large area substrate processing, e.g., 2940 mm by 3370 mm, also known as Gen. 10.5, has proven challenging.

Accordingly, what is needed in the art are improved positioning systems for processing large area substrates and methods related thereto.

### SUMMARY

Embodiments of the present disclosure include processing systems for processing large area substrates and positioning systems and methods used therewith. In particular, embodiments herein include substrate processing and interferometry systems used in the manufacturing of flat panel displays (FPDs), and methods related thereto.

In one embodiment, a processing system features a motion stage movably disposed on a base surface, one or more X-position interferometers, and a plurality of Y-position interferometers. Each of the one or more X-position interferometers includes an X-position mirror fixedly coupled to the motion stage and an X-axis stationary module fixedly coupled a non-moving surface of processing system. Each of the X-axis stationary modules is positioned to direct coherent radiation to a respective X-position mirror. Each of the plurality of Y-position interferometers include one of a first or second Y-position mirror fixedly coupled to the motion stage, the first or second Y-position mirror in an orthogonal relationship to the one or more X-position mirrors, and one of a first or a second Y-axis stationary module fixedly coupled to a non-moving surface of the processing system. Here, each of the first and second Y-axis stationary modules are positioned to direct coherent radiation towards at least one of the first and second at least one of the Y-position mirrors when the Y-position interferometers thereof are in an active mode.

In another embodiment, a method of processing a substrate includes positioning a substrate on a motion stage of a processing system and forming an exposure pattern on a surface of the substrate. Here, the processing system has an X-axis and a cross Y-axis orthogonally related to the X-axis. Forming an exposure pattern on the surface of the substrate includes sequential repetitions of moving the substrate along the Y-axis while simultaneously exposing a portion of the substrate surface to radiation from a plurality of lithography exposure sources and indexing the substrate along the X-axis to position an unpatterned portion of the substrate surface under the plurality of lithography exposure sources. Herein, operation of the lithography exposure sources is coordinated with the movement of the motion stage using position information received from one of a plurality of Y-position interferometers.

In another embodiment, a computer readable medium has instructions stored thereon for a method of processing a substrate. The method includes positioning a substrate on a motion stage of a processing system and forming an exposure pattern on a surface of the substrate. Here, the processing system has an X-axis and a cross Y-axis orthogonally related to the X-axis. Forming an exposure pattern on the surface of the substrate includes sequential repetitions of moving the substrate along the Y-axis while simultaneously exposing a portion of the substrate surface to radiation from a plurality of lithography exposure sources and indexing the substrate along the X-axis to position an unpatterned portion of the substrate surface under the plurality of lithography exposure sources. Herein, operation of the lithography exposure sources is coordinated with the movement of the motion stage using position information received from one of a plurality of Y-position interferometers.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1A illustrates a direct write lithography (DWL) process, according to the prior art.

FIG. 1B is a schematic plan view illustrating an interferometer used in embodiments described herein, according to one embodiment.

FIG. 2A is a schematic isometric view of a processing system having a portion thereof removed, according to one embodiment.

FIG. 2B is a schematic plan view of the processing system shown in FIG. 2A taken along line 2B-2B.

FIG. 2C is a close-up view of a portion of the processing system shown in FIG. 2B, according to one embodiment.

FIG. 2D illustrates a remotely positioned interference detector, according to one embodiment.

FIG. 2E is a schematic view illustrating the arrangement of the Y-position mirrors shown in FIGS. 2A-2B.

FIGS. 3A-3D illustrate elements of a signal stitching method using the processing system described in FIGS. 2A-2E, according to one embodiment.

FIG. 4 is a flow diagram setting forth a method of processing a substrate, according to one embodiment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure include processing systems for processing large area substrates and positioning systems and methods used therewith. In particular, embodiments herein include substrate processing and interferometry systems used in the manufacturing of flat panel displays (FPDs), and methods related thereto. The interferometry systems and methods herein are adaptable to any process or system where precision positioning or position tracking of a large area substrate is desired.

In a conventional interferometry system each respective plane mirror will be at least as long as the as a stroke length required to process a substrate as the motion stage travels along the cross axis of the beam measurement path. The precision of the interferometry measurement, and thus the error in the position of the motion stage, is determined at least in part by the flatness of the plane mirrors coupled to the motion stage. Undesirable non-uniformities in the surface of the plane mirror, e.g., an uneven or undulating surface, will result in a path length change in the path of the second beam which cannot be distinguished from actual positional differences or motion changes in the motion stage. For example, in some embodiments one or more of the plane mirrors will have a flatness of less than about 1λ, where λ is equal to 633 nm, such as less than about 317 nm (½λ), for example less than about 159 nm (¼λ) across the polished length thereof in order to meet the positioning error budget of the DWL processing system.

Unfortunately, the cost, availability, and, or, manufacturing lead time of plane mirrors having suitable flatness and required length for the precision requirements of the next generation of large area substrate DWL systems are undesirably extreme or otherwise prohibitive. Therefore, in embodiments herein, at least one or more axis of the dual axis system features a plurality of plane mirrors arranged in a coplanar series to provide measurements along a desired stroke length of the motion stage as it travels along the cross axis.

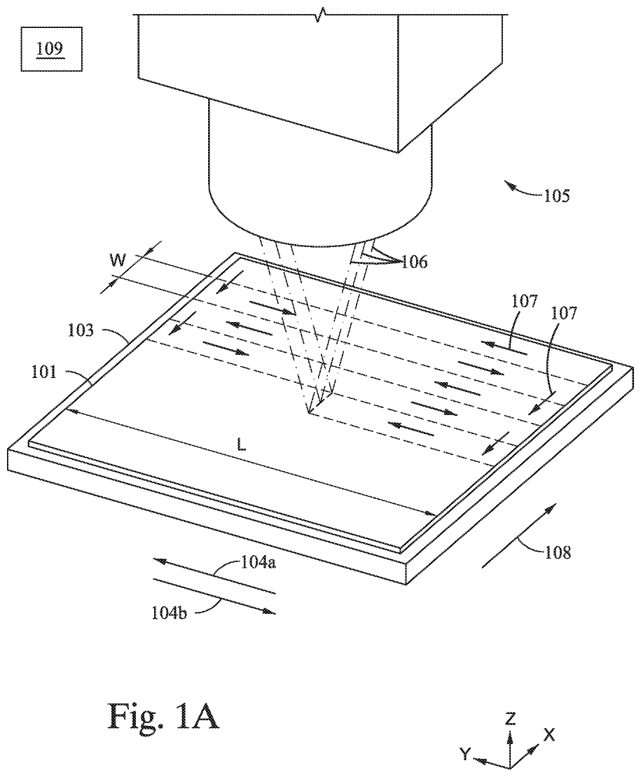

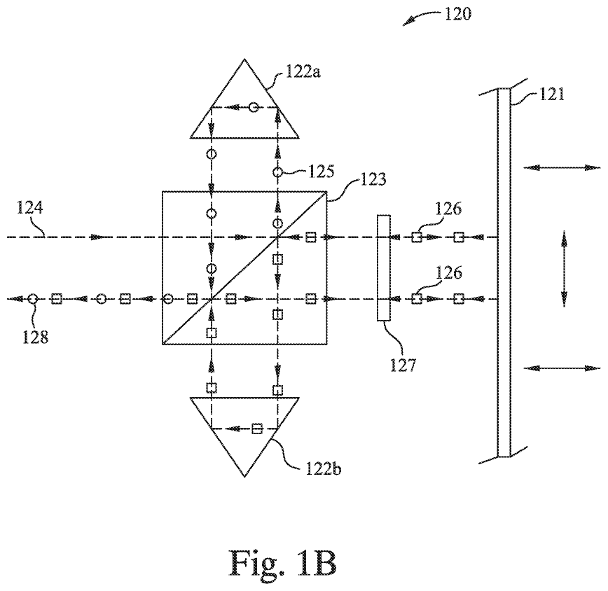

FIG. 1B illustrates an interferometer 120 used with the interferometry systems described herein, according to one embodiment. Here, the interferometer 120 is a differential plane mirror interferometer (DPMI) featuring a measurement mirror 121, a plurality of retroreflectors 122a-b, a beam splitter 123, and an interference detector (not shown). Typically, the measurement mirror 121 features a plane surface and is movable along dual axes which are respectively orthogonal and parallel to the plane surface. Here, the first and second retroreflectors 122a-b comprise right angle prisms each positioned to face one another and each positioned where the respective hypotenuses thereof are orthogonally related to the plane surface of the measurement mirror 121.

The beam splitter 123 is a polarizing beam splitter (PBS) which divides an input beam 124 of coherent radiation, e.g., a laser beam, into a reference beam, e.g., the first beam 125, and a measurement beam, e.g., the second beam 126. The first beam 125 is directed towards, and reflected by, the first retroreflector 122a back towards the beam splitter 123. The second beam 126 is directed towards, and reflected by, the measurement mirror 121 in a first measurement pass.

The interferometer 120 further includes a quarter waveplate 127 disposed between the measurement mirror 121 and the beam splitter 123. During a first measurement pass, the second beam 126 passes through the quarter waveplate 127 when traveling towards the measurement mirror 121 and again when returning therefrom. Traveling through the quarter waveplate 127 twice shifts the polarization state of the second beam 126 by 90° with respect it its original state. The second beam 126, having a shifted polarization state, is then directed by the beam splitter 123 towards the second retroreflector 122b. Once reflected by the second retroreflector 122b, the second beam 126 is then again directed by the beam splitter 123 towards the measurement mirror 121 and reflected therefrom in a second measurement pass. During the second measurement pass the second beam 126 again passes through the quarter waveplate 127 when traveling towards the measurement mirror 121 and when returning therefrom thus again shifting the polarization state by 90°. After the second measurement pass the second beam 126 travels through the beam splitter 123 where the first and second beams 125 and 126 combine to form an output beam 128. Herein, the output beam 128 exits the beam splitter 123 in a path parallel to the input beam 124.

Typically, the output beam 128 is directed to an interference detector (not shown) which determines the difference in the path lengths traveled by the first beam 125 and the second beam 126 based on an interference pattern formed by the recombination thereof.

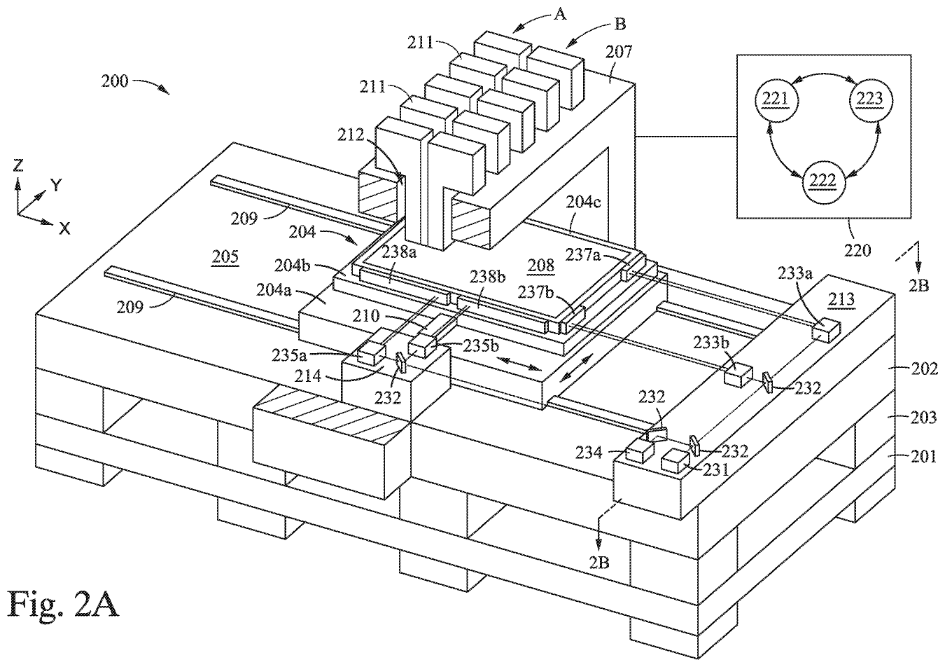

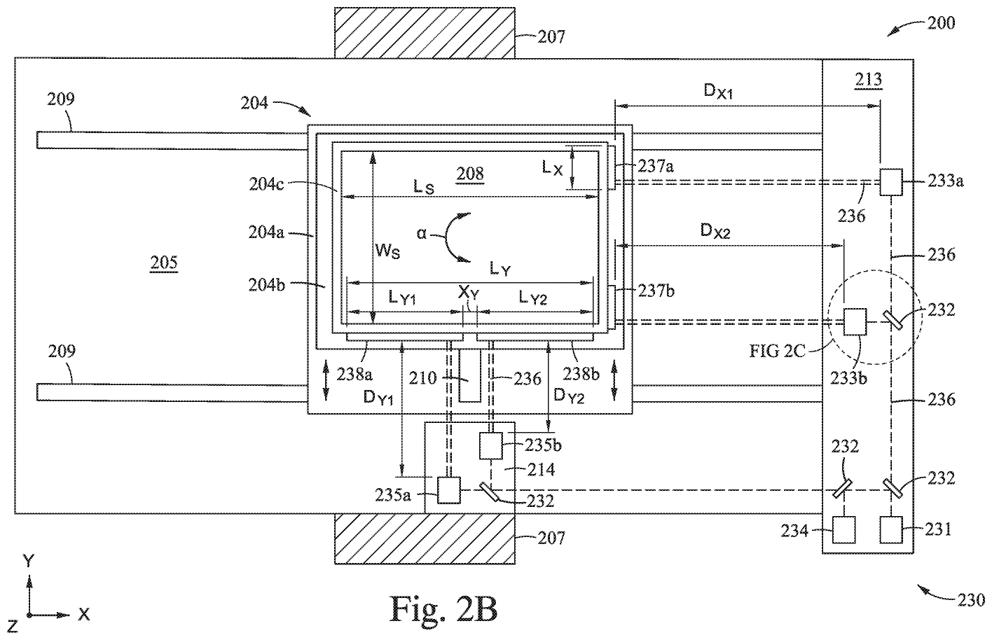

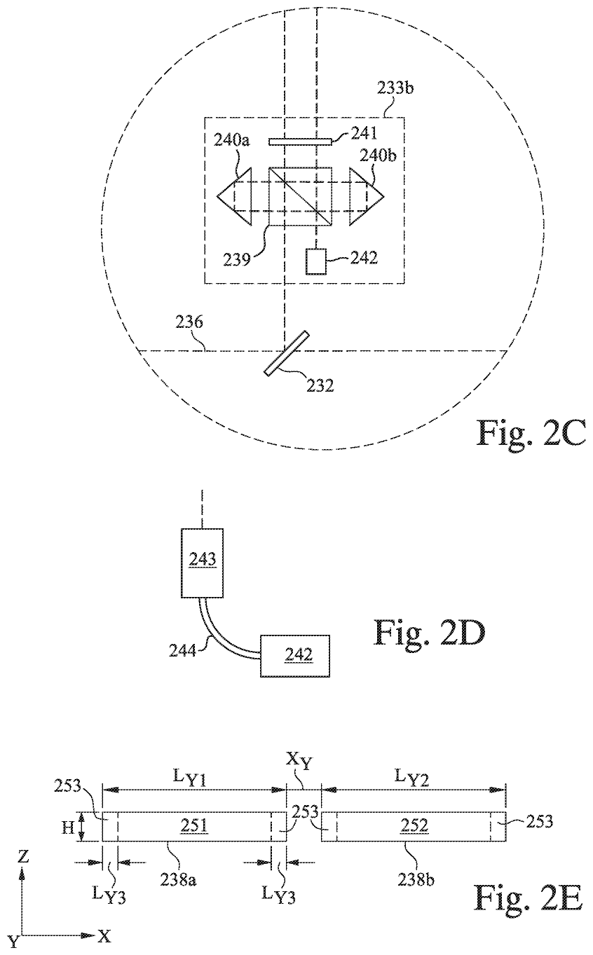

FIG. 2A is a schematic isometric view of a direct write lithography (DWL) system, herein a processing system 200, having a portion thereof, in particular a portion of the bridge 207, removed for clarity of description. FIG. 2B is a schematic view of the processing system 200 shown in FIG. 2A taken along line 2B-2B. FIG. 2C is a close up view of a portion of FIG. 2B illustrating the individual components of a stationary module described herein. FIG. 2D is a close up view of an interference detector, according to one embodiment. FIG. 2D is a schematic view illustrating the arrangement of the Y-position mirrors shown in FIGS. 2A-2B.

The processing system 200 features a frame 201, a base 202 disposed on the frame 201 and vibrationally isolated therefrom by a plurality of vibration isolators 203 interposed therebetween, and a motion stage 204 disposed on a planar base surface 205. The processing system 200 further includes a bridge 207 coupled to the base 202. The bridge 207 spans the base surface 205 and is separated therefrom by a height sufficient to allow the motion stage 204, and a substrate 208 disposed thereon, to pass therebetween. In other embodiments, supports of the bridge 207 are disposed on the base surface 205 and the bridge 207 spans a portion of the base surface 205 disposed between the supports.

Herein, the motion stage 204 is multi-axis linear translation motion stage, e.g., an X-Y motion stage. The motion stage 204 features a first platform 204a disposed on the base surface 205 and movable relative thereto in an X-direction, a second platform 204b disposed the first platform 204a and movable relative thereto in a Y-direction, and a substrate carrier 204c disposed on, and fixedly coupled to, the second platform 204b. Herein, the X-direction is orthogonally related to the span direction of the bridge 207 and the Y-direction is parallel to the span direction of the bridge 207, and thus orthogonally related to the X-direction. In some embodiments, the motion stage 204, and thus the substrate carrier 204c, is sized to support a substrate 208 having at least a width W_{S} of about 2940 mm and a length L_{S} of about 3390 mm, i.e., a Gen. 10.5 substrate or larger. In other embodiments, the motion stage 204, and thus the substrate carrier 204c, is sized to support a substrate 208 having at least a width W_{S} of about 360 mm and a length L_{S} of about 465 mm, i.e., a Gen. 2 substrate or larger.

Herein, the motion of one or both of the first and second platforms 204a-b is provided by a plurality of air bearings (not shown) respectively coupled thereto. In some embodiments, the processing system 200 further includes one or more first linear guides 209 extending in the X-direction, such as one or more parallel rails, disposed on the base surface 205. The plurality of air bearings are used to move the motion stage in the X-direction along the first linear guides 209 and the second platform 204b in the Y-direction along one or more second liner guides 210.

The bridge 207 supports a plurality of optical modules 211 which are disposed through an opening 212 therein. The plurality of optical modules 211 are positioned to face the base surface 205, and thus face the substrate 208, as the motion stage 204 travels between the bridge 207 and the base surface 205. Here, the plurality of optical modules 211 are arranged in two or more rows A-B orthogonal to the X-axis. Each of the rows A-B is used to expose a pattern on a portion of the substrate 208 as the motion stage 204 travels therebeneath.

Typically, each of the optical modules 211 includes one or more of a focus sensor, an image sensor, and a lithography exposure source. The image sensor, e.g., a camera, is used to detect one or more fiducial features (not shown), e.g. alignment marks, formed in or on a patterned surface of a substrate 208. The detected fiducial features are used by the system controller 220 to determine pattern offset information therefrom, such as one or both of X-Y translational offset and rotational offset from desired or reference X-Y and, or, rotational pattern positions. The focus sensor is used to determine the distance between the surface of the substrate 208 and the optical module 211, i.e., a Z-distance. Each of the lithography exposure sources direct and, or, focus electromagnetic radiation, e.g., one or more UV laser beams, to, on, or beneath a surface of a resist layer deposited on the substrate 208 to form an exposure pattern therein. Typically, a system controller 220 of the processing system 200 uses the pattern offset information and the Z-distance to direct the operation of the lithography exposure sources to form the desired exposure pattern in the resist layer.

The system controller 220 includes a programmable central processing unit (CPU) 221 that is operable with a memory 222 (e.g., non-volatile memory) and support circuits 223. The support circuits 223 are conventionally coupled to the CPU 221 and comprise cache, clock circuits, input/output subsystems, power supplies, and the like, and combinations thereof coupled to the various components of the processing system 200, to facilitate control of a DWL process. The CPU 221 is one of any form of general purpose computer processor used in an industrial setting, such as a programmable logic controller (PLC), for controlling various components and sub-processors of the processing system 200. The memory 222, coupled to the CPU 221, is non-transitory and is typically one or more of readily available memories such as random access memory (RAM), read only memory (ROM), floppy disk drive, hard disk, or any other form of digital storage, local or remote.

Typically, the memory 222 is in the form of a computer-readable storage media containing instructions (e.g., non-volatile memory), that when executed by the CPU 221, facilitates the operation of the processing system 200. The instructions in the memory 222 are in the form of a program product such as a program that implements the methods of the present disclosure. The program code may conform to any one of a number of different programming languages. In one example, the disclosure may be implemented as a program product stored on computer-readable storage media for use with a computer system. The program(s) of the program product define functions of the embodiments (including the methods described herein).

Illustrative computer-readable storage media include, but are not limited to: (i) non-writable storage media (e.g., read-only memory devices within a computer such as CD-ROM disks readable by a CD-ROM drive, flash memory, ROM chips or any type of solid-state non-volatile semiconductor memory) on which information is permanently stored; and (ii) writable storage media (e.g., floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure. In some embodiments, the methods described herein, or portions thereof, are performed by one or more application specific integrated circuits (ASICs), field-programmable gate arrays (FPGAs), or other types of hardware implementations. In some other embodiments, the processes described herein are performed by a combination of software routines, ASIC(s), FPGAs and, or, other types of hardware implementations. Herein, the system controller 220 is used to simultaneously control and coordinate the operation of the motion stage 204 and the plurality of optical modules 211 using positioning and motion information provided by the dual axis interferometry system.

The dual axis interferometry system includes a coherent light source 231, such as a laser source, a plurality of beam splitters 232, an X-axis interferometry system, and a Y-axis interferometry system. In some embodiments, the dual axis interferometry system 230 further includes a wavelength compensator 234. The wavelength compensator 234 is used to detect variations in the wavelength of the beam 236 due to changes in the refractive index of the atmosphere through which the beam 236 travels. The wavelength compensation information is communicated to the system controller 220 which uses the information to compensate for undesirable interferometer measurement variations due to changes in atmospheric conditions such as temperature, humidity, and barometric pressure.

Here, the X-axis interferometry system includes a plurality of X-axis interferometers. In some embodiments, each of the X-axis interferometers is a differential plane mirror interferometer (DPMI), such as the interferometer 120 described in FIG. 1B. Herein, each of the X-axis interferometers features an X-axis stationary module 233a-b and a corresponding X-position mirror 237a-b. Each of the X-position mirrors 237a-b is fixedly coupled to the substrate carrier 204c and is positioned to reflect coherent radiation, such as a laser beam 236, received from a respective X-axis stationary module 233a-b back theretowards.

Here, each of the X-axis stationary modules 233a-b comprises a fixed arrangement of optical components, i.e., an optical assembly, such as shown in FIG. 2C. The optical assembly includes a polarizing beam splitter 239, a plurality of retroreflectors 240a-b, and a quarter waveplate 241. In some embodiments, such as shown in FIG. 2C, the X-axis stationary modules 233a-b further include an interference detector 242 positioned proximate thereto. In other embodiments, such as shown in FIG. 2D, the X-axis stationary modules 233a-b include an interference detector 242 positioned remotely from the optical assembly. In those embodiments, the optical assembly further includes an optical receiver 243 which transmits an output beam received from the polarizing beam splitter 239 to the remotely positioned interference detector 242 using a fiber optic cable 244 coupled therebetween. Here, the optical assembly is disposed on, and fastened to, a non-moving surface 213 of the processing system 200. In some embodiments, one or more components of the optical assembly are separately fastened to the non-moving surface 213.

The X-axis interferometers are used to determine distances D_{X1} and D_{X2} between the X-position mirrors 237a-b and corresponding X-axis stationary modules 233a-b, the speed of the motion stage traveling in the X-direction during substrate processing, or both. Using more than one X-axis interferometer further enables a measurement of the yaw a of the substrate carrier 204c, i.e., a difference between a longitudinal axis of the substrate carrier 204c and a direction of travel thereof. Each of the X-position mirrors 237a b have a length L_{X} equal to, or more than, a desired stroke length of the motion stage 204 in the Y-direction, i.e., a Y-stroke length.

The Y-axis interferometry system includes a plurality of Y-axis stationary modules 235a-b and a plurality of Y-position mirrors 238a-b. Each of the Y-axis stationary modules 235a-b includes a fixed arrangement of optical components, such as the optical assembly shown in FIGS. 2C-2D. Each of the Y-axis stationary modules 235a-b further includes an interference detector 242 positioned proximate to the optical assembly or positioned remotely therefrom and in optical communication therewith. Each of the Y-axis stationary modules 235a-b or one or more of the individual components thereof, is fastened to a non-moving surface 214 of the processing system 200. Each of the Y-position mirrors 238a-b is fixedly coupled to the substrate carrier 204c in an orthogonal relationship to the plurality of X-position mirrors 236a-b.

In some embodiments, at least one of the Y-position mirrors 238a-b has a respective length L_{Y1} or L_{Y2} between about 1 m and about 1.4 m, or more than about 1 m for a processing system configured to process Gen 10.5 substrate sizes. In other embodiments, the sizes of the position mirrors are scaled for processing systems configured to process different sized substrates. Here, the Y-position mirrors 238a-b are spaced apart by a distance X_{Y} so that the Y-position mirrors span a distance L. In some embodiments, the distance X_{Y} is between about 1 mm and about 20 mm, or about 1 mm or more, such as about 3 mm or more, or example about 6 mm or more. Typically, the X and Y-position mirrors described herein include a polished surface, such as the polished surface 251-252 shown in FIG. 2E, having a desirable flatness and unpolished surfaces 253 disposed at the ends thereof. In some embodiments, a width L_{Y3} of an unpolished surface 253 at the ends of the X and Y position mirrors is between about 1 mm and about 50 mm, such as between about 3 mm and about 50 mm, for example between about 5 mm and about 50 mm.

During substrate processing the Y-axis interferometry system is used to determine one or both of the position and the motion of the motion stage 204 as the substrate carrier 204c, and thus the substrate 208, is moved (indexed) along the X axis. In embodiments herein, the Y-axis interferometry system is active from the beginning to the end an X-axis processing stroke having an X-stroke length. In some embodiments, such as in embodiments where the plurality of optical modules 211 are arranged in two or more rows, such as rows A-B, the X-axis stroke length will be less than the length L_{S} of the to be processed substrate 208.

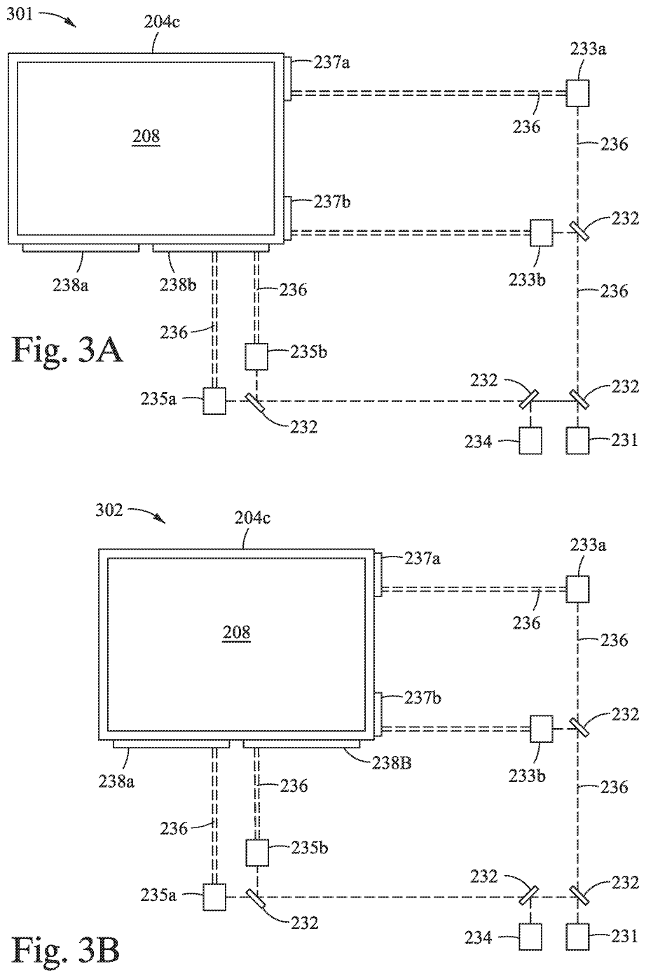

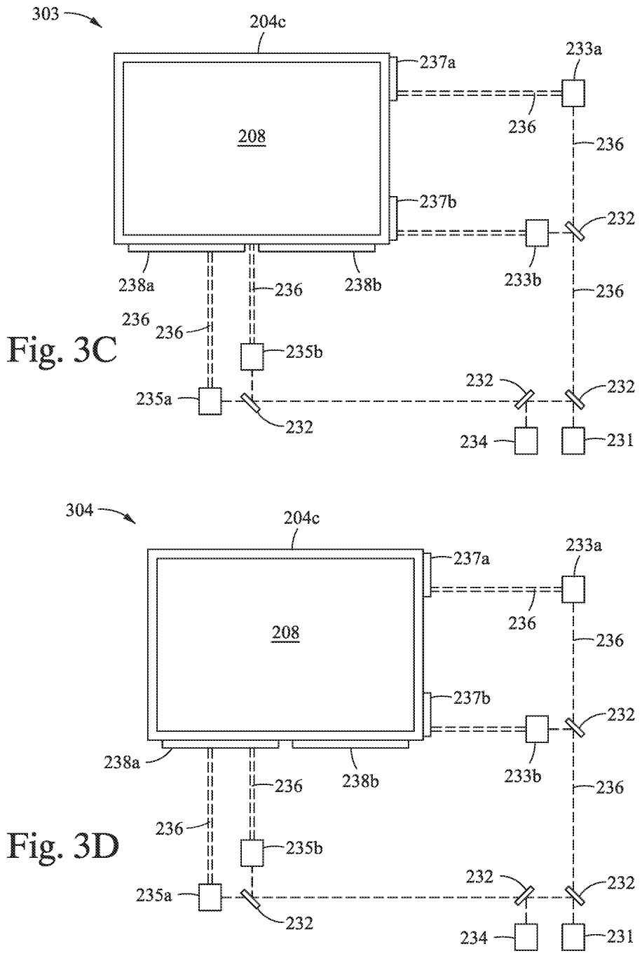

In a conventional interferometry system, a single Y-position mirror (not shown) would be at least as long as the X-stroke length a beam reflected thereby would be used to provide continuous motion stage position information to a system controller. Herein, the Y-position mirrors 238a-b do not have sufficient individual lengths L_{Y1} or L_{Y2} to span a desired stroke length of the motion stage 204 as the substrate 208 is stepped (indexed) in an X-direction during substrate processing. Therefore, the plurality of Y-position interferometers described herein, and the individual components thereof, are positioned so that at least one beam of coherent radiation is reflected from a polished surface of a Y-position mirror 238a or 238b at all times during the X-axis processing stroke. Further, embodiments herein include a signal stitching method, described in FIGS. 3A-3D, which enables the use of the plurality of Y-position mirrors 238a-b along a desired X-stroke length. The signal stitching method compensates for the difference, i.e., Y-axis offset, in the optical path lengths of the first and second Y-position interferometers.

FIGS. 3A-3D illustrate relative positions 301-304 of the substrate carrier 204c and the dual axis interferometry system 230 during a substrate processing sequence, according to one embodiment. In FIG. 3A the substrate carrier 204c of the motion stage (first and second platforms not shown), and thus the substrate 208, is positioned in a first processing position 301 at or near the beginning of the X-axis substrate processing stroke. In the first processing position 301 the second Y-axis interferometer, i.e., the second Y-axis stationary module 235b and the second Y-position mirror 238b, is in an active mode and the first Y-axis interferometer, i.e., the first Y-axis stationary module 235a and the first Y-position mirror 238a, is not in an active mode. Herein, a Y-axis interferometer is in an active mode when the components thereof are in an active configuration and when the information received therefrom is used by the system controller (shown in FIG. 2A) to coordinate the movement and position of the substrate carrier 204c and the operation of the lithography exposure sources (not shown). The components of a Y-axis interferometer are in an active configuration when they are operating to transmit and receive one or more laser beams to and from a polished surface of a Y-position mirror 238a or 238b. In the first processing position 301 the first Y-axis stationary module 235a is not in an active configuration because no beams are reflected by the polished surface of the Y position mirror 238a.

In the second processing position 302 the second Y-axis interferometer remains in the active mode and the first Y-axis interferometer is in a partially active mode. A Y-axis interferometer is in a partially active mode when the components thereof are in an active configuration, but information received therefrom is not simultaneously used by the system controller to coordinate the movement of the motion stage and the operation of the lithography exposure sources. Here, information received from the second Y-axis interferometer (in the partially active mode) is used, in combination with position information received from the second Y-axis interferometer (in the active mode), to initialize the first Y-axis interferometer. Initializing a Y-axis interferometer in a partially active mode comprises determining a Y-axis offset between the Y-axis interferometer in the partially active mode and a Y-axis interferometer an active mode. In the second processing position 302 the Y-axis offset is the difference between DY1 and DY2 determined when both Y-axis interferometers are in an active configuration. Typically, the Y-axis offset is stored in the memory of the system controller or a component thereof.

In FIG. 3C, the substrate carrier 204c is shown in a third processing position 303. In the third processing position 303 the first Y-axis interferometer is in the active mode and the second Y-axis interferometer not in an active mode. In the third processing position 303 information received from the first Y-axis interferometer, in combination with the Y-axis offset stored during the initialization of the first Y-axis interferometer, is simultaneously used by the system controller coordinate the movement of the motion stage and the operation of the lithography exposure sources.

In FIG. 3D, the substrate carrier 204c is shown in a fourth processing position 304 at or near the end of the substrate processing sequence. In the fourth processing position 304 the first Y-axis interferometer is in the active mode and the second Y-axis interferometer is not in the active mode and is therefore inactive. In the fourth processing position 304 information received from the first Y-axis interferometer, in combination with the Y-axis offset stored during the initialization of the first Y-axis interferometer, is simultaneously used by the system controller coordinate the movement of the motion stage and the operation of the lithography exposure sources.

In FIGS. 3A-3D the substrate carrier 204c is positioned distal from the X-axis stationary modules 233a-b in the first processing position 301, and is subsequently indexed theretowards in processing positions 302-304. In other embodiments the direction of substrate travel during processing is reversed. For example, in some embodiments the substrate carrier 204c is positioned proximate to the X-axis stationary modules 233a-b at the beginning of a substrate processing sequence and is subsequently indexed away therefrom during the substrate processing sequence. In those embodiments, the first Y-axis interferometer is in an active mode and the second Y-axis interferometer is in an inactive mode at the beginning of the substrate processing sequence. In those embodiments, Y-axis offset information is used to initialize the second Y-axis interferometer in the middle of the substrate processing sequence. In those embodiments, the second Y-axis interferometer is in an active mode at the end of the substrate processing sequence and the first Y-axis interferometer is an inactive mode at the end of the substrate processing sequence.

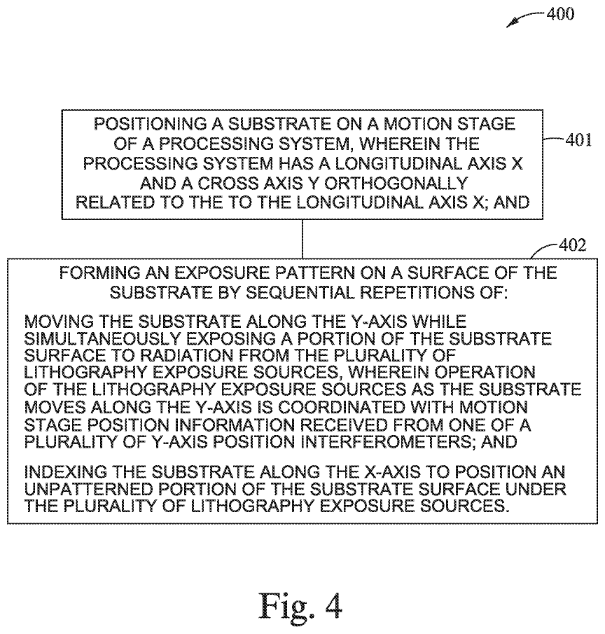

FIG. 4 is a flow diagram setting forth a method 400 of processing a substrate, according to one embodiment. At activity 401 the method 400 includes positioning a substrate on a motion stage of a processing system. Here, the processing system has an X-axis in a first direction thereof and a Y-axis orthogonally related to the X-axis.

At activity 402 the method 400 includes forming an exposure pattern on a surface of the substrate. Here, forming the exposure pattern comprises sequential repetitions of moving the substrate along the Y-axis while simultaneously exposing a portion of the substrate surface to radiation from the plurality of lithography exposure sources and indexing the substrate along the X-axis to position an unpatterned portion of the substrate surface under the plurality of lithography exposure sources. Here, operation of the lithography exposure sources is coordinated with motion stage position information received from one of a plurality of Y-position interferometers using a system controller.

In some embodiments, moving the substrate along the Y-axis comprises moving the substrate in a first direction along the Y-axis while simultaneously exposing a portion of the substrate surface to radiation from the plurality of lithography exposure sources, i.e., writing an exposure pattern in the resist layer. In some embodiments, the substrate is then moved in a second direction along the Y-axis, opposite the first direction, without exposing the substrate surface to radiation. In those embodiments, the substrate is returned to a desired starting Y-position before, or simultaneously with, indexing of the substrate along the X-axis, followed by scanning the substrate in the first direction along the Y-axis. Simultaneously, a portion of the substrate surface is exposed to radiation from the plurality of lithography exposure sources. Sequential repetitions of writing an exposure pattern in the resist layer, returning the substrate to a starting Y-position and indexing the substrate along the X-axis results in a plurality of mono-directional print paths. In other embodiments, the substrate is indexed along the Y-axis before scanning the substrate in the second direction along the Y-axis while simultaneously exposing a portion of the substrate surface to radiation from the plurality of lithography exposure sources to write an exposure pattern in the resist layer. Sequential repetitions of writing an exposure pattern in the resist layer in the first direction, indexing the substrate along the X-axis, and writing an exposure pattern in the resist layer in a second direction form a serpentine print path.

Embodiments herein beneficially enable the use of a plurality of plane mirrors arranged in coplanar series to span a stroke length of a dual axis motion stage. Using a series of shorter plane mirrors arranged in series desirably reduces cost and manufacturing time of processing systems used in the next generation of large area flat panel display (FPD) manufacturing.

While the foregoing is directed to embodiments of the present disclosure, other and further embodiments of the disclosure may be devised without departing from the basic scope thereof, and the scope thereof is determined by the claims that follow.

1. A processing system, comprising:
a motion stage movably disposed on a base surface, the motion stage comprising a substrate carrier for supporting a to-be-processed substrate;
a plurality of X-position interferometers, each comprising:
an X-position mirror of a plurality of X-position mirrors, each fixedly coupled to the motion stage; and
an X-axis stationary module of a plurality of X-axis stationary modules, each fixedly coupled to a non-moving surface of the processing system, wherein each X-axis stationary module is positioned to direct coherent radiation towards a corresponding X-position mirror; and
a Y-position interferometry system, comprising:
a first Y-position mirror and a second Y-position mirror arranged in a coplanar series, wherein
respective lengths of each of the Y-position mirrors are less than a length of a to-be-processed substrate;
each of the Y-position mirrors are fixedly coupled to the motion stage, and
each of the Y-position mirrors are disposed in an orthogonal relationship to the X-position mirrors; and
a first Y-axis stationary module and a second Y-axis stationary module, wherein
each of the Y-axis stationary modules are fixedly coupled to a non-moving surface of the processing system, and
each of the Y-axis stationary modules are positioned to direct coherent radiation towards at least one of the first and second Y-position mirrors when the at least one Y-position mirror is arranged in an active mode therewith; and
a wavelength compensator associated with both of the X-axis stationary module and the first Y-axis stationary module to detect variations in the coherent radiation.

2. The processing system of claim 1, wherein each of the first and second Y-axis stationary modules comprises a beam splitter, a plurality of retroreflectors, and a quarter waveplate.

3. The processing system of claim 2, wherein each of plurality of Y-position interferometers further comprises an interference detector.

4. The processing system of claim 1, further comprising a plurality of optical modules disposed above the base surface and facing theretowards.

5. The processing system of claim 4, further comprising a bridge disposed above the base surface, wherein
a span direction of the bridge is orthogonal to reflective surfaces of the Y-position mirrors,
the plurality of optical modules are disposed through an opening in the bridge, and
the plurality of optical modules are arranged in two or more rows in a direction parallel to the span direction.

6. The processing system of claim 1, wherein the motion stage comprises:
a first platform movably disposed along an X-axis of the processing system;
a second platform disposed on the first platform and movable relative thereto along a Y-axis, wherein the Y-axis is orthogonally related to the X-axis; and
the substrate carrier disposed on the second platform and fixedly coupled thereto.

7. The processing system of claim 6, wherein the first and second Y-position mirrors are fixedly coupled to the substrate carrier.

8. The processing system of claim 7, wherein polished surfaces of the first and second Y-position mirrors are spaced apart by about 1 mm or more.

9. The processing system of claim 8, wherein a flatness of each of the first and second Y-position mirrors is less than about 633 nm across a respective first and second polished lengths thereof.

10. The processing system of claim 9, wherein the processing system further comprises a plurality of optical modules disposed above the base surface and facing theretowards, and wherein each of the plurality of optical modules comprise one or a combination of a focus sensor, an image sensor, and a lithography exposure source.

11. A method of processing a substrate, comprising:
positioning a substrate on a motion stage of a processing system, wherein the processing system has an X-axis and a Y-axis orthogonally related to the to the X-axis, and wherein the processing system comprises:
the motion stage movably disposed on a base surface, the motion stage comprising a substrate carrier for supporting a to-be-processed substrate;
a plurality of X-position interferometers, each comprising:
an X-position mirror of a plurality of X-position mirrors, each fixedly coupled to the motion stage; and
an X-axis stationary module of a plurality of X-axis stationary modules, each fixedly coupled a non-moving surface of processing system, wherein each X-axis stationary module is positioned to direct coherent radiation towards a corresponding X-position mirror; and
a Y-position interferometry system, comprising:
a first Y-position mirror and a second Y-position mirror arranged in a coplanar series, wherein
respective lengths of each of the Y-position mirrors are less than a length of a to-be-processed substrate;
each of the Y-position mirrors are fixedly coupled to the motion stage, and
each of the Y-position mirrors are disposed in an orthogonal relationship to the X-position mirrors; and
a first Y-axis stationary module and a second Y-axis stationary module, wherein
each of Y-axis stationary modules are fixedly coupled to a non-moving surface of the processing system, [[and]]
each of the Y-axis stationary modules are positioned to direct coherent radiation towards at least one of the first and second Y-position mirrors when the at least one Y-position mirror is arranged in an active mode therewith; and
a wavelength compensator associated with both of the X-axis stationary module and the first Y-axis stationary module to detect variations in the coherent radiation; and
forming an exposure pattern on a surface of the substrate by sequential repetitions of:
moving the substrate along the Y-axis while simultaneously exposing a portion of the substrate surface to radiation from a plurality of lithography exposure sources, wherein operation of the lithography exposure sources is coordinated with motion stage position information received from the Y-position interferometry system; and
indexing the substrate along the X-axis to position an unpatterned portion of the substrate surface under the plurality of lithography exposure sources.

12. The method of claim 11, wherein the motion stage position information comprises a Y-axis offset that is determined when the motion stage is disposed in a position such that that each of the Y-axis stationary modules directs coherent radiation at a different one of the first and second Y-position mirrors to form a first Y-position interferometer and a second Y-position interferometer respectively.

13. (canceled)

14. The method of claim 12, wherein the coherent radiation reaching the first Y-position interferometer has a first path length and the coherent radiation reaching the second Y-position interferometer has a second path length when the first and second Y-position interferometers are both disposed in the active mode, and wherein the Y-axis offset is a difference between the first path length and the second path length.

15. The method of claim 14, wherein the motion stage comprises:
a first platform movably disposed along an X-axis of the processing system;
a second platform disposed on the first platform and movable relative thereto along a Y-axis, wherein the Y-axis is orthogonally related to the X-axis; and
the substrate carrier disposed on the second platform and fixedly coupled thereto, wherein the first and second Y-position mirrors are fixedly coupled to the substrate carrier.

16. The processing system of claim 1, further comprising:
a computer readable medium having instructions stored thereon for a method of processing a substrate, the method comprising:
positioning a substrate on the motion stage of a processing system;
forming an exposure pattern on a surface of the substrate by sequential repetitions of:
moving the substrate along the Y-axis while simultaneously exposing a portion of the substrate surface to radiation from a plurality of lithography exposure sources, wherein operation of the lithography exposure sources is coordinated with motion stage position information received from the Y-position interferometry system; and
indexing the substrate along the X-axis to position an unpatterned portion of the substrate surface under the plurality of lithography exposure sources.

17. The processing system of claim 16, wherein the motion stage position information comprises a Y-axis offset that is determined when the motion stage is disposed in a position such each of the Y-axis stationary modules directs coherent radiation at a different one of the first and second Y-position mirrors to form a first Y-position interferometer and a second Y-position interferometer respectively.

18. (canceled)

19. The processing system of claim 17, wherein the first Y-position interferometer has a first path length and the second Y-position interferometer has a second path length when the first and second Y-position interferometers are both disposed in the active mode, and wherein the Y-axis offset is a difference between the first path length and the second path length.

20. The processing system of claim 19, wherein the motion stage comprises:
a first platform movably disposed along a longitudinal X-axis of the processing system;
a second platform disposed on the first platform and movable relative thereto along a Y-axis, wherein the Y-axis is orthogonally related to the X-axis; and
the substrate carrier disposed on the second platform and fixedly coupled thereto, wherein the first and second Y-position mirrors are fixedly coupled to the substrate carrier.

21. The processing system of claim 1, further comprising one or more lithography exposure sources for exposing a pattern on a surface of a to-be-processed substrate, wherein both the first Y-position mirror and the second Y-position mirror are arranged so that Y-position information obtained from both must be used to control the lithography exposure sources during exposing the pattern along the length of the to-be-processed substrate.

22. The processing system of claim 1, wherein the processing system is a lithography processing system configured to expose a pattern onto a surface of a to-be-processed substrate, and wherein the individual lengths of each of the Y-position mirrors are less than a stroke length required to complete exposure of the pattern onto the surface of the to-be-processed substrate.

23. A lithography processing system, comprising:
a motion stage movably disposed on a base surface, the base surface having an X axis and a Y axis orthogonally related to the to the X axis;
a substrate carrier disposed on the motion stage; and
a Y-position interferometry system comprising a first Y-position mirror and a second Y-position mirror arranged in a coplanar series parallel to the Y-axis, and a wavelength compensator positioned in a beam path of the Y-position interferometry system to detect variations in the wavelength of a beam in the beam path, wherein
the lithography processing system is configured to expose a pattern onto a surface of a to-be-processed substrate,
the individual lengths of each of the Y-position mirrors are less than a stroke length that is required to complete exposure of the pattern onto the surface of the to-be-processed substrate, and
the stroke length is measured parallel to the Y-axis.
